(19) United States
(12) Patent Application Publication
(10) Pub. No.: US 2007/0184652 A1
(43) Pub. Date: Aug. 9, 2007

(54) Method for preparing a metal feature surface prior to electroless metal deposition

(75) Inventors: Aaron Frank, Murphy, TX (US); David Gonzalez JR., Plano, TX (US)

Correspondence Address: TEXAS INSTRUMENTS INCORPORATED, P O BOX 655474, M/S 3999, DALLAS, TX, 75265, US

(73) Assignee: Texas Instruments, Incorporated, Dallas, TX (US)

(21) Appl. No.: 11/349,355

(22) Filed: Feb. 7, 2006

(51) Int. Cl. H01L 21/44; H01L 23/52

(52) U.S. Cl. 438/648; 438/678; 438/687; 438/725; 257/750; 257/758

(57) ABSTRACT

The present invention provides a method for manufacturing an interconnect and an integrated circuit. The method for manufacturing the interconnect, in one embodiment, includes forming a first metal feature (310) over a substrate, subjecting the first metal feature (310) to a hydrogen containing plasma (410), the hydrogen containing plasma (410) configured to remove organic residue (320) from an exposed surface of the first metal feature (310), and electroless depositing a second metal feature (510) on the first metal feature (310) having been subjected to the hydrogen containing plasma (410).

### TECHNICAL FIELD OF THE INVENTION

The present invention is directed, in general, to a method for preparing a metal feature and, more specifically, to a method for preparing a metal feature surface prior to electroless metal deposition.

### BACKGROUND OF THE INVENTION

The continual demand for enhanced integrated circuit performance has resulted in, among other things, a dramatic reduction of semiconductor device geometries, and continual efforts to optimize the performance of every substructure within any semiconductor device. A number of improvements and innovations in fabrication processes, material composition, and layout of the active circuit levels of a semiconductor device have resulted in very high-density circuit designs. Increasingly dense circuit design has not only improved a number of performance characteristics, it has also increased the importance of, and attention to, semiconductor material properties and behaviors.

The increased packing density of the integrated circuit generates numerous challenges to the semiconductor manufacturing process. Every device should be smaller without damaging the operating characteristics thereof. High packing density, low heat generation, and low power consumption, with good reliability and long operation life must be maintained without any functional device degradation. Increased packing density of integrated circuits is usually accompanied by smaller feature size.

As integrated circuits become denser, the widths of interconnect layers that connect transistors and other semiconductor devices of the integrated circuit are reduced. As the widths of interconnect layers and semiconductor devices decrease, their resistance increases. Accordingly, semiconductor manufacturers seek to create smaller and faster devices by using, for example, a copper interconnect instead of a traditional aluminum interconnect. Unfortunately, copper is very difficult to etch in most semiconductor process flows. Therefore, damascene processes have been proposed and implemented to form copper interconnects.

Damascene methods usually involve forming a trench and/or an opening in a dielectric layer that lies beneath and on either side of the copper-containing structures. Once the trenches or openings are formed, a blanket layer of the copper-containing material is formed over the entire device. Electrochemical deposition (ECD) is typically the only practical method to form a blanket layer of copper. The thickness of such a layer must be at least as thick as the deepest trench or opening. After the trenches or openings are filled with the copper-containing material, the copper-containing material over them is removed, e.g., by chemical-mechanical polishing (CMP), so as to leave the copper-containing material in the trenches and openings (e.g., forming an interconnect) but not over the dielectric or over the uppermost portion of the trench or opening.

After forming the copper interconnect, a capping layer may be formed thereover. The capping layer is designed to act as a diffusion barrier between the copper in the interconnect and other features located thereby, as well as an etch stop layer for subsequent interconnects. Electroless cobalt plating may be used to selectively deposit a cobalt alloy capping layer on top of the copper interconnect after CMP. This process is catalyzed by the copper interconnect surface, which allows the cobalt alloy capping layer to selectively deposit on the copper interconnect (e.g., it does not deposit on the surrounding dielectric).

The electroless cobalt plating, however, currently has certain drawbacks. One such drawback is the lack of coverage of the copper interconnect that results after the electroless cobalt plating. This lack of coverage may, and often will, negatively affect the electrical performance of the interconnect. Other problems may also result.

Accordingly, what is needed in the art is a method for manufacturing an interconnect that does not experience the aforementioned problems of the prior art.

### SUMMARY OF THE INVENTION

To address the above-discussed deficiencies of the prior art, the present invention provides a method for manufacturing an interconnect and an integrated circuit. The method for manufacturing the interconnect, in one embodiment, includes forming a first metal feature over or within a substrate, subjecting the first metal feature to a hydrogen containing plasma, the hydrogen containing plasma configured to remove organic residue from an exposed surface of the first metal feature, and electroless depositing a second metal feature on the first metal feature having been subjected to the hydrogen containing plasma. The method for manufacturing the integrated circuit, in addition to the formation of the interconnect, includes forming one or more transistors over a substrate, the interconnect configured to connect the one or more transistors and form an operational integrated circuit.

### BRIEF DESCRIPTION OF THE DRAWINGS

For a more complete understanding of the present invention, reference is now made to the following descriptions taken in conjunction with the accompanying drawings, in which:

FIGS. 1-5 illustrate sectional views of detailed manufacturing steps instructing how one might, in an advantageous embodiment, manufacture an interconnect structure in accordance with the principles of the present invention; and

FIG. 6 illustrates a sectional view of an integrated circuit (IC) incorporating interconnect structures constructed according to the principles of the present invention.

### DETAILED DESCRIPTION

The present invention is based, at least in part, on the acknowledgement that organic residue on an upper surface of a metal feature may inhibit the electroless metal deposition of a second metal feature thereon. Having made this acknowledgement, the present invention further acknowledges that conventional wet cleans are ineffective at removing the organic residue without extreme damage to the metal feature. Based upon the aforementioned recognitions, as well as substantial experimentation, the present invention recognizes that a hydrogen containing plasma could be used to remove a substantial portion, if not all, of the organic residue from the metal feature prior to the electroless metal deposition of the second metal feature. The present invention further recognizes that the hydrogen containing plasma can be conducted without severe damage to the metal feature.

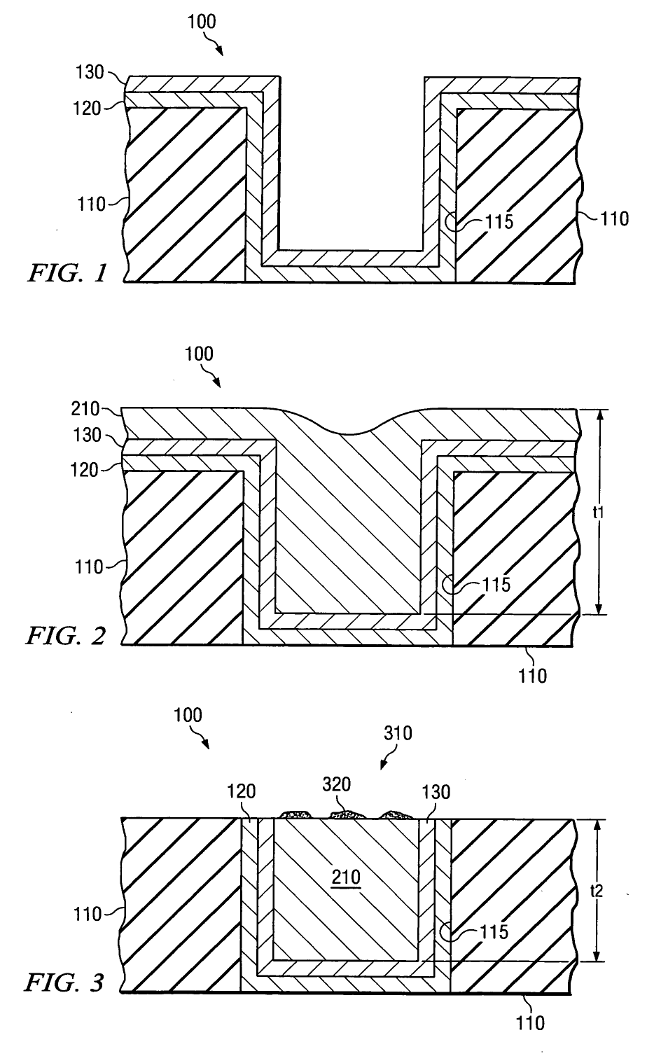

Turning now to FIGS. 1-5, illustrated are sectional views of detailed manufacturing steps instructing how one might, in an advantageous embodiment, manufacture an interconnect structure in accordance with the principles of the present invention. FIG. 1 illustrates an interconnect structure 100 at an initial stage of manufacture. The interconnect structure 100 illustrated in FIG. 1 includes a dielectric layer 110, such as an interlevel dielectric layer located over a gate structure. The dielectric layer 110 may comprise any dielectric material known by those skilled in the art, such as silicon dioxide, a low dielectric constant material, or a non-silicon dielectric material. Located within the dielectric layer 110 is an opening 115. One skilled in the art understands how to form such an opening 115, including conducting conventional lithographic and etching techniques on a blanket layer of dielectric material.

Conventionally formed within the opening 115 in the embodiment shown are a barrier layer 120 and seed layer 130. In the illustrative embodiment shown, the barrier layer 120 and seed layer 130 are also formed over an upper surface of the dielectric layer 110. As those skilled in the art appreciate, the barrier layer 120 is configured to substantially reduce, if not prevent, a metal located within the opening 115 in the dielectric layer 110 from diffusing into nearby structures. Similarly, as those skilled in the art appreciate, the seed layer 130 is configured to provide a surface upon which a subsequent metal layer can easily be deposited.

The materials chosen for the barrier layer 120 and seed layer 130 are generally dependent on the particular material being used for the first metal layer 210 (FIG. 2). In the given embodiment, however, the first metal layer 210 (FIG. 2) comprises copper, and thus the barrier layer 120 might comprise tantalum, tantalum nitride, Tungsten alloys, Ruthenium or ruthenium alloys, and the seed layer 130 might comprise a copper or copper alloy seed layer. It goes without saying that these materials would most likely change if the first metal layer 210 (FIG. 2) were to comprise a different material, for instance tungsten. Accordingly, the present invention should not be limited to any specific material.

Turning now to FIG. 2, illustrated is a sectional view of the interconnect structure 100 of FIG. 1, after formation of a first metal layer 210 over the barrier layer 120 and seed layer 130, as well as within the opening 115. In the illustrative embodiment of FIG. 2 the first metal layer 210 is formed to an appropriate thickness (t₁) to fill the opening 115, thus the first metal layer 210 is also formed over an upper surface of the dielectric layer 110.

In the illustrative embodiment shown in FIG. 2, the first metal layer 210 comprises copper, however, those skilled in the art appreciate that other similar materials that are currently known or hereafter discovered may comprise the first metal layer 210. In the particular embodiment where the first metal layer 210 comprises copper, the first metal layer 210 may be formed using a conventional electroplating process. As this process is conventional, no further detail will be given. Were the first metal layer 210 to comprise a different material than copper, an appropriate formation technique would be used to form this different material.

Turning to FIG. 3, illustrated is a sectional view of the interconnect structure 100 illustrated in FIG. 2, after polishing the first metal layer 210, seed layer 130 and barrier layer 120 from the top surface of the dielectric layer 110, resulting in a first metal feature 310 having a lesser thickness (t₂). Those skilled in the art understand the conventional processes that may be used to polish the first metal layer 210, seed layer 130 and barrier layer 120. In the embodiment shown, however, a conventional chemical-mechanical polishing (CMP) process is used.

It has been observed that the conventional process used to polish the first metal layer 210, seed layer 130 and barrier layer 120 often includes a corrosion inhibitor additive therein to prevent corrosion of the first metal layer 210 during the polishing thereof. The present invention has recognized that this corrosion inhibitor (e.g., in one instance Benzotriazole (BTA)) often remains on the upper surface of the first metal feature 310 as organic residue 320 after completing the polishing of the first metal layer 210. As mentioned above, the organic residue 320 on the first metal feature 310 inhibits the electroless metal deposition of a second metal feature 510 (FIG. 5) thereon. While the polishing is currently believed to be a source of the organic residue 320, other sources may also exist. Accordingly, the present invention should not be limited to any particular source for the organic residue 320.

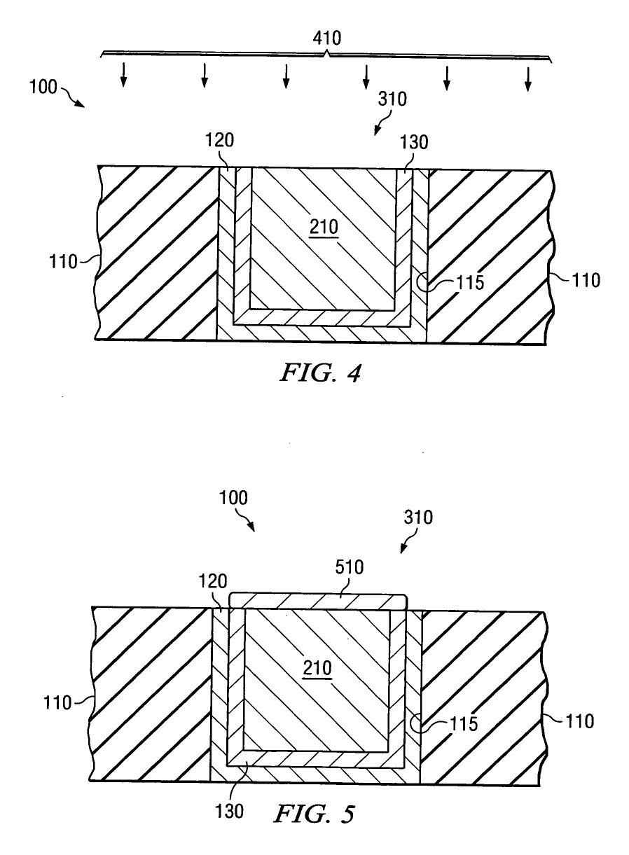

Turning now to FIG. 4, illustrated is a sectional view of the interconnect structure 100 of FIG. 3 as it is being subjected to a hydrogen containing plasma 410. The hydrogen containing plasma 410, in the illustrative embodiment, is configured to remove a portion, if not all, of the organic residue 320 from an exposed surface of the first metal feature 310. Advantageous to the present invention, the hydrogen containing plasma 410 removes enough of the organic residue 320 from the surface of the first metal feature 310 that a second metal feature 510 (FIG. 5) can be appropriately electroless deposited thereon.

The hydrogen containing plasma 410 illustrated in FIG. 4, and all aspects related thereto, may vary greatly while staying within the scope of the present invention. One particular aspect of the hydrogen containing plasma 410 that may vary is the time period the first metal feature 310, and thus the organic residue 320, is subjected to the hydrogen containing plasma 410. For instance, in one embodiment the organic residue 320 may be subjected to the hydrogen containing plasma for a time period ranging from about 0.5 seconds to about 180 seconds. In an alternative embodiment, however, the organic residue 320 may be subjected to the hydrogen containing plasma for a time period ranging from about 20 seconds to about 60 seconds. In essence, the time period for subjecting the organic residue 320 to the hydrogen containing plasma 410 is generally related to the amount of organic residue 320, and difficulty of its removal. Thus, other time periods, whether presently known or hereafter discovered, could also be used.

Similarly, the hydrogen containing plasma 410 may be generated with a variety of different conditions. For example, the hydrogen containing plasma 410 might use an RF power ranging from about 50 watts to about 5000 watts, a pressure ranging from about 50 mTorr to about 3000 mTorr, and a temperature ranging from about 25° C. to about 350° C., among others. Additionally, the hydrogen containing plasma 410 may use hydrogen gas, ammonia, or another hydrogen source to provide the hydrogen thereto. In the instance wherein hydrogen gas is used, the gas flow of hydrogen might range from about 2 sccm to about 3000 sccm. In the instance wherein ammonia gas is used as the hydrogen source, the gas flow of ammonia might range from about 2 sccm to about 3000 sccm. Other gases, such as argon, helium or nitrogen, could also be included with the hydrogen source. While many different ranges have been given for the hydrogen containing plasma, the present invention should not be limited to any specific ranges.

Turning now to FIG. 5, illustrated is a sectional view of the interconnect structure 100 of FIG. 4 after electroless depositing a second metal feature 510 over, and in this embodiment on, the first metal feature 310. The electroless deposition of the second metal feature 510 allows for the selective deposition of the second metal feature 510 on the first metal feature 310, and not the surrounding dielectric layer 110. Accordingly, in the embodiment of FIG. 5, the second metal feature 510 is only located on the first metal feature 310, and not the dielectric layer 110. Having removed the organic residue 320 from the exposed surface of the first metal feature 310 prior to the electroless deposition of the second metal feature 510, better, if not perfect, coverage of the first metal feature 310 may be obtained. Thus, the interconnect structure 100 illustrated in FIG. 5 does not have the coverage issues that an interconnect structure manufactured using conventional processes would.

Preferably, the second metal feature 510 includes cobalt or a cobalt alloy. For example, useful cobalt alloys include cobalt-tungsten alloys, cobalt-phosphorus alloys, cobalt-tin alloys, cobalt-boron alloys, and ternary alloys, such as cobalt-tungsten-phosphorus and cobalt-tungsten-boron. The second metal feature 510 may also include, however, other metals, metal alloys and dopants, such as nickel, tin, titanium, tantalum, tungsten, molybdenum, platinum, iron, niobium, palladium, nickel cobalt alloys, doped cobalt, doped nickel alloys, nickel iron alloys, boron, phosphorous, and combinations thereof. The second metal feature 510 may be deposited to have a thickness of about 5000 nm or less, such as between about 50 nm and about 2000 nm. However, other thicknesses could be used.

Cobalt alloys, such as cobalt-tungsten, may be deposited by adding tungstic acid or tungstate salts, such as sodium tungstate, ammonium tungstate, and combinations thereof. Phosphorus for the cobalt-tungsten-phosphorus deposition may be obtained by using phosphorus-containing reducing agents, such as hypophosphite. Cobalt alloys, such as cobalt-tin, may be deposited by adding stannate salts including stannic sulfate, stannic chloride, and combinations thereof. The metals salts may be in the electroless solution at a concentration between about 0.5 g/L and about 30 g/L, among others.

In one aspect, the second metal feature 510 is deposited from a metallic electroless solution containing at least one metal salt and at least one reducing agent. Suitable metal salts include chlorides, sulfates, sulfamates, or combinations thereof. One example of a metal salt is cobalt chloride. The metal salt may be in the electroless solution at a concentration between about 0.5 g/L and about 30 g/L.

Suitable reducing agents include sodium hypophosphite, hydrazine, formaldehyde, and combinations thereof. The reducing agents may also include borane-containing reducing agents, such as dimethylamine borane and sodium borohydride. The reducing agents may, without limitation, have a concentration between about 1 g/L and about 30 g/L of the electroless solution.

The electroless solution may further include between about 0.01 g/L and about 50 g/L of one or more additives to improve deposition of the metal. Additives may include surfactants, complexing agents (carboxylic acids, such as sodium citrate and sodium succinate), pH adjusting agents (sodium hydroxide, potassium hydroxide), stabilizers (thiourea, glycolic acid), and combinations thereof.

In general, the metallic electroless solution may be applied to the first metal feature 310 surface at a rate between about 50 ml/min and about 2,000 ml/min, such as between about 700 ml/min and about 900 ml/min. The metallic electroless solution may be applied for about 30 seconds to about 180 seconds at a temperature between about 60° C. and about 90° C., among others.

In one aspect, a cobalt electroless composition for forming the second metal feature 510 may include about 20 g/L of cobalt sulfate, about 50 g/L of sodium citrate, about 20 g/L of sodium hypophosphite, and a sufficient amount of potassium hydroxide to provide a pH of between about 9 and about 11. This electroless composition may be applied to the substrate surface for about 120 seconds at a flow rate of about 750 ml/min and at a temperature of about 80° C. In another aspect, a cobalt-tungsten layer may be deposited by the addition of about 10 g/L of sodium tungstate.

It should be noted that the subjecting of the first metal feature 310 to the hydrogen containing plasma 410 and the formation of the second metal feature 510 might be performed in the same processing tool. For instance, a clustering tool could be used wherein the subjecting of the first metal feature 310 to the hydrogen containing plasma 410 occurs in a chamber of the clustering tool, and the formation of the second metal feature 510 occurs in a different chamber of the same clustering tool. Alternatively, however, the subjecting of the first metal feature 310 to the hydrogen containing plasma 410 and the formation of the second metal feature 510 may be performed in completely separate processing tools.

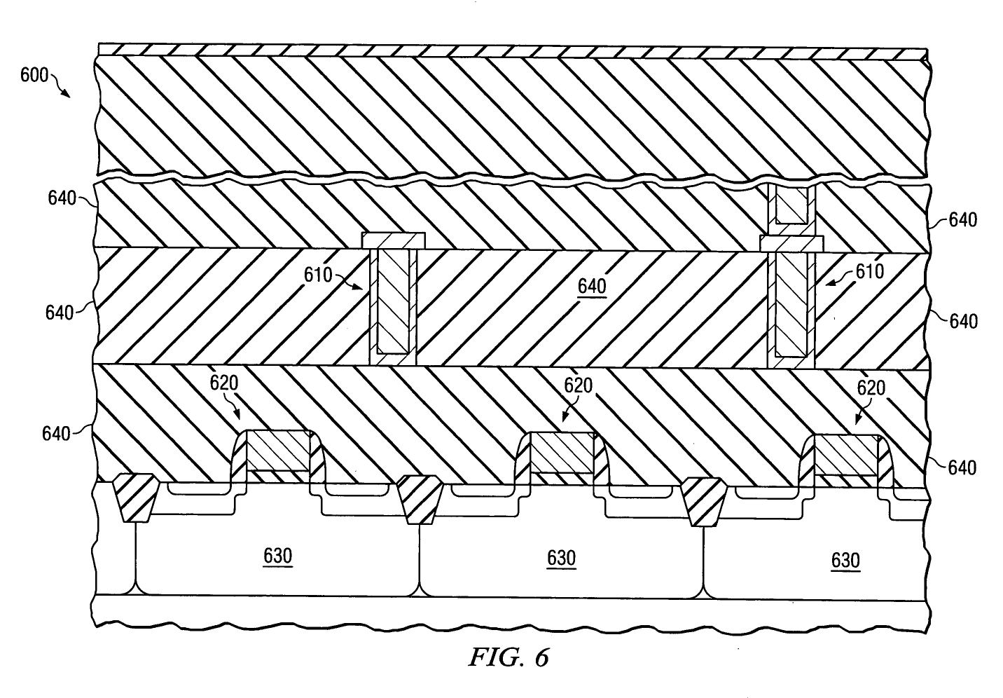

Referring finally to FIG. 6, illustrated is a sectional view of an integrated circuit (IC) 600 incorporating interconnect structures 610 constructed according to the principles of the present invention. The IC 600 may include devices, such as transistors used to form CMOS devices, BiCMOS devices, Bipolar devices, as well as capacitors or other types of devices. The IC 600 may further include passive devices, such as inductors or resistors, or it may also include optical devices or optoelectronic devices. Those skilled in the art are familiar with these various types of devices and their manufacture. In the particular embodiment illustrated in FIG. 6, the IC 600 includes transistor devices 620 located over a semiconductor substrate 630. Further located over the transistor devices 620 are dielectric layers 640. As is further illustrated, the interconnect structures 610 may be located within the dielectric layers 640 to interconnect various devices, thus, forming the operational integrated circuit 600.

Although the present invention has been described in detail, those skilled in the art should understand that they could make various changes or substitutions herein without departing from the spirit and scope of the invention in its broadest form.

What is claimed is:

1. A method for manufacturing an interconnect, comprising:
forming a first metal feature over or within a substrate;
subjecting the first metal feature to a hydrogen containing plasma, the hydrogen containing plasma configured to remove organic residue from an exposed surface of the first metal feature; and
electroless depositing a second metal feature on the first metal feature having been subjected to the hydrogen containing plasma.

2. The method as recited in claim 1 wherein the first metal feature is a copper damascene metal feature.

3. The method as recited in claim 1 wherein the second metal feature is a cobalt metal feature.

4. The method as recited in claim 1 wherein the cobalt metal feature is a cobalt alloy.

5. The method as recited in claim 1 wherein the first metal feature is subjected to the hydrogen containing plasma for a period of time ranging from about 0.5 seconds to about 180 seconds.

6. The method as recited in claim 1 wherein the hydrogen containing plasma uses an RF power ranging from about 50 watts to about 5000 watts, a temperature ranging from about 25° C. to about 350° C., and a pressure ranging from about 50 mtorr to about 3000 mtorr.

7. The method as recited in claim 1 wherein the hydrogen containing plasma uses hydrogen gas or ammonia as a hydrogen source.

8. The method as recited in claim 1 wherein the subjecting and the electroless plating occur in a same processing tool.

9. The method as recited in claim 1 wherein forming a first metal feature includes forming a layer of the first metal to a first thickness, and then polishing the layer of the first metal to a second lesser thickness, the polishing leaving at least a portion of the organic residue.

10. An interconnect manufactured using the process of claim 1.

11. A method for manufacturing an interconnect, comprising:
forming a first metal feature over or within a substrate;
subjecting the first metal feature to a hydrogen containing plasma, the hydrogen containing plasma using an RF power ranging from about 50 watts to about 5000 watts, a temperature ranging from about 25° C. to about 350° C., and a pressure ranging from about 50 mtorr to about 3000 mtorr, and thereby configured to remove organic residue from an exposed surface of the first metal feature; and
electroless depositing a second metal feature on the first metal feature having been subjected to the hydrogen containing plasma.

12. The method as recited in claim 11 wherein the first metal feature is subjected to the hydrogen containing plasma for a period of time ranging from about 0.5 seconds to about 180 seconds.

13. The method as recited in claim 11 wherein the hydrogen containing plasma uses hydrogen gas or ammonia as a hydrogen source.

14. A method for manufacturing an integrated circuit, comprising:
forming one or more transistors over a substrate; and
forming one or more interconnects over the one or more transistors to form an operational integrated circuit, including;
forming a first metal feature over the substrate;
subjecting the first metal feature to a hydrogen containing plasma, the hydrogen containing plasma configured to remove organic residue from an exposed surface of the first metal feature; and
electroless depositing a second metal feature on the first metal feature having been subjected to the hydrogen containing plasma.

15. The method as recited in claim 14 wherein the second metal feature is a cobalt metal feature.

16. The method as recited in claim 14 wherein the first metal feature is subjected to the hydrogen containing plasma for a period of time ranging from about 0.5 seconds to about 180 seconds.

17. The method as recited in claim 14 wherein the hydrogen containing plasma uses a power ranging from about 50 Watts to about 5000 Watts, a temperature ranging from about 25° C. to about 350° C., and a pressure ranging from about 50 mtorr to about 3000 mtorr.

18. The method as recited in claim 14 wherein the hydrogen containing plasma uses hydrogen gas or ammonia as a hydrogen source.

19. The method as recited in claim 14 wherein forming a first metal feature includes forming a layer of the first metal to a first thickness, and then polishing the layer of the first metal to a second lesser thickness, the polishing leaving at least a portion of the organic residue.

20. An integrated circuit manufactured using the process of claim 14.
